(19) United States
(12) Patent Application Publication
(10) Pub. No.: US 2008/0246124 A1
(43) Pub. Date: Oct. 9, 2008

(54) PLASMA TREATMENT OF INSULATING MATERIAL

(76) Inventors: James Mathew, Boise, ID (US); Prashant Raghu, Boise, ID (US); Jaydeb Goswami, Boise, ID (US)

Correspondence Address: WELLS ST. JOHN P.S., 601 W. FIRST AVENUE, SUITE 1300, SPOKANE, WA, 99201, US

(21) Appl. No.: 11/696,262

(22) Filed: Apr. 4, 2007

(51) Int. Cl. H01L 21/302; H01L 23/58

(52) U.S. Cl. 257/632; 438/710; 257/E23.001; 257/E21.214

(57) ABSTRACT

A method is disclosed which includes forming an opening in an insulating material, performing a plasma process to introduce nitrogen into a portion of the insulating material to thereby form a nitrogen-containing region at least on an inner surface of the opening, and, after forming the nitrogen-containing region, performing an etching process through the opening. A device is disclosed which includes an insulating material comprising a nitrogen-enhanced region that is proximate an opening that extends through the insulating material and a conductive structure positioned within the opening.

### BACKGROUND OF THE INVENTION

1. Technical Field

The present disclosure generally relates to the field of semiconductor manufacturing, and, more particularly, to plasma treatment of various insulating materials on a semiconductor device.

2. Description of the Related Art

The manufacturing of semiconductor devices may involve many process steps. For example, semiconductor fabrication typically involves processes such as deposition processes, etching processes, thermal growth processes, various heat treatment processes, ion implantation, photolithography, etc. Such processes may be performed in any of a variety of different combinations to produce semiconductor devices that are useful in a wide variety of applications.

In general, there is a constant drive within the semiconductor industry to increase the operating speed and efficiency of various integrated circuit devices, e.g., microprocessors, memory devices, and the like. This drive is fueled by consumer demands for computers and electronic devices that operate at increasingly greater speeds and efficiency. This demand for increased speed and efficiency has resulted in a continual reduction in the size of semiconductor devices, e.g., transistors, capacitors, etc., as well as an increase in the packing density of such devices on an integrated circuit device. That is, many components of a typical field effect transistor (FET), e.g., channel length, junction depths, gate insulation thickness, and the like, are reduced. For example, all other things being equal, the smaller the channel length of the transistor or the thinner the gate insulation layer, the faster the transistor will operate. Thus, there is a constant drive to reduce the size, or scale, of the components of a typical transistor to increase the overall speed of the transistor, as well as integrated circuit devices incorporating such transistors. Manufacturing integrated circuit devices is a very complex and competitive business. Customers frequently demand that successive products, or versions thereof, have increased performance capabilities relative to prior products or versions.

Conductive structures, such as conductive lines and vias, are provided in modern integrated circuit devices to conductively interconnect various semiconductor devices, e.g., transistors, resistors, capacitors, etc., to form an integrated circuit that is useful for a particular purpose. Typically, such conductive structures are formed in multiple layers or levels of insulating material that are positioned above the semiconductor devices, which are formed in and on a layer of semiconducting material, e.g., silicon. The exact wiring pattern established using such a conductive interconnection may vary depending upon the particular application.

In forming such conductive structures, one or more etching processes are performed to form an opening in the insulating material that will ultimately be filled with a conductive material, such as a metal, e.g., aluminum, copper, etc. After the opening is initially formed, one or more subsequent cleaning processes may be performed in an attempt to remove any undesirable materials from the bottom of the opening prior to forming the conductive structure in the opening. For example, one or more etching processes may be performed in an attempt to remove residual polymer materials resulting from the etching process that was performed to define the initial opening, or any oxide material that may have formed at the bottom of the opening. Such “clean-up” etching processes are performed in an attempt to ensure that a good conductive connection can be established between the conductive structure to be formed in the opening and an underlying structure, e.g., a semiconductor device formed in a semiconducting material, a previously formed conductive line or structure that is formed in an underlying insulating material, etc. However, during such clean-up etching processes, the size, e.g., critical dimension, of the original opening may be undesirably increased beyond that of its desired or target size. Such lack of dimensional control of the size of openings for conductive structures to be formed in an insulating material may be problematic for several reasons. For example, due to the loss of dimensional control during such clean-up etching processes, the resulting conductive structures formed therein have an increased size, which may result in problems, such as potential electrical shorts between such conductive structures.

### BRIEF DESCRIPTION OF THE DRAWINGS

The invention may be understood by reference to the following description taken in conjunction with the accompanying drawings, in which like reference numerals identify like elements, and in which:

FIGS. 1-7 depict one illustrative process flow for the plasma treatment of an insulating material as disclosed herein; and

FIG. 8 is an illustrative example of a semiconductor device comprised of a plasma treated insulating material as described herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

Although various regions and structures shown in the drawings are depicted as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the subject matter disclosed herein.

As will be recognized by those skilled in the art after a complete reading of the present application, the subject matter disclosed herein may be employed in connection with the formation of conductive structures for a variety of semiconductor devices, e.g., transistors, capacitors, resistors, diodes, etc., and it may be employed in connection with the formation of a variety of different types of integrated circuit devices, e.g., memory devices, microprocessors, application specific integrated circuits (ASICs), etc. Additionally, the methodologies and structures disclosed herein may be implemented in connection with the formation of conductive structures at any level of an integrated circuit device, e.g., at the level where such conductive structures actually contact a device formed in the substrate, or structures where the conductive structures are positioned within one or more levels of insulating material formed above the substrate.

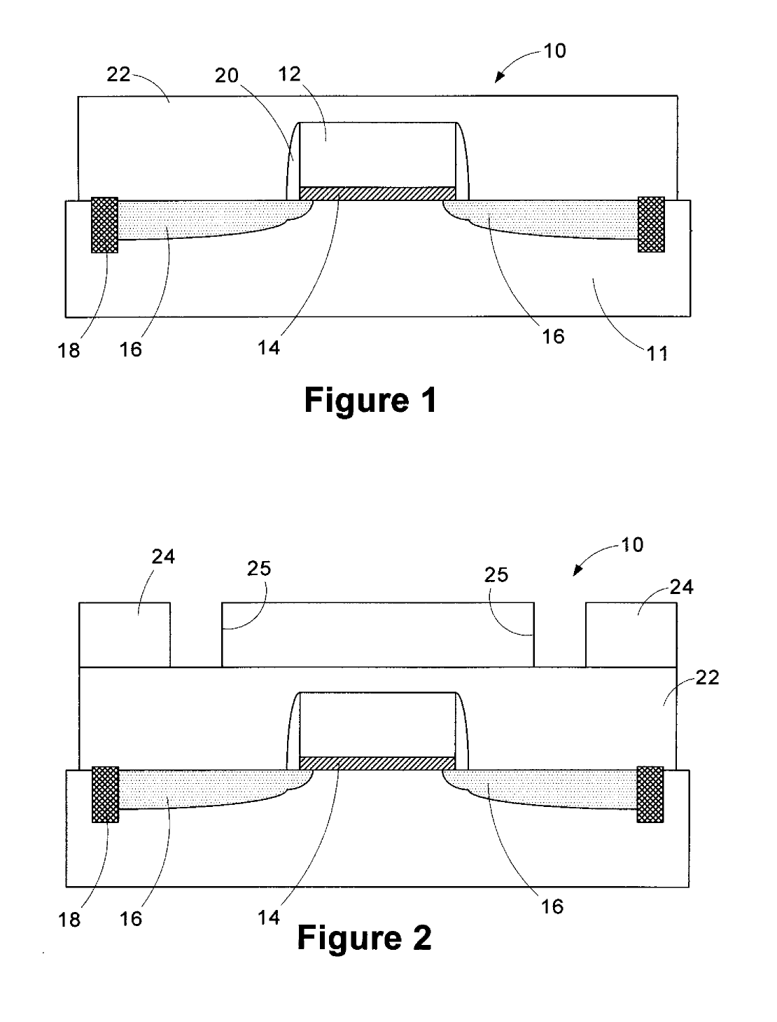

As shown in FIG. 1, an illustrative semiconductor device 10, e.g., a transistor, is formed on a semiconducting substrate 11, e.g., silicon. As set forth above, the illustrative device 10 is intended to be representative of any of a variety of different semiconductor devices. The substrate 11 is also intended to be representative in nature of any type of semiconducting material or structure, e.g., bulk silicon, silicon-germanium (Si—Ge) or silicon-on-insulator (SOI) structures. Thus, the term substrate should be understood to be used in the very broad sense throughout the specification.

The illustrative transistor 10 comprises a gate electrode 12, a gate insulation layer 14, source/drain regions 16, an isolation structure 18 and a sidewall spacer 20. The materials of construction of such a device 10 as well as the techniques employed in manufacturing such a device 10 are well known to those skilled in the art and thus will not be repeated herein.

As shown in FIG. 1, an illustrative insulating material 22 may be formed above the transistor 10. The insulating material 22 may be comprised of a variety of materials and it may be formed by a variety of techniques. For example, the insulating material 22 may be comprised of a doped or undoped silicon glass, a phosphorous doped silicon glass (PSG), etc. The insulating material 22 may be formed by performing a variety of processes, e.g., a chemical vapor deposition (CVD) process, a plasma enhanced chemical vapor deposition (PECVD) process, a spin-coating process, etc. The thickness of the insulating material 22 may also vary depending upon the particular application. In one illustrative example, the thickness may range from approximately 1-2 μm.

Next, as shown in FIG. 2, a patterned masking layer 24 may be formed above the insulating material 22. The patterned masking layer 24 comprises a plurality of openings 25 that correspond to openings (not shown in FIG. 2) that will be formed in the insulating material 22. The patterned masking layer 24 may be formed from a variety of materials and it may be formed using a variety of techniques. In one illustrative example, the patterned masking layer 24 may be comprised of a photoresist material that may be formed using traditional photolithography tools and techniques.

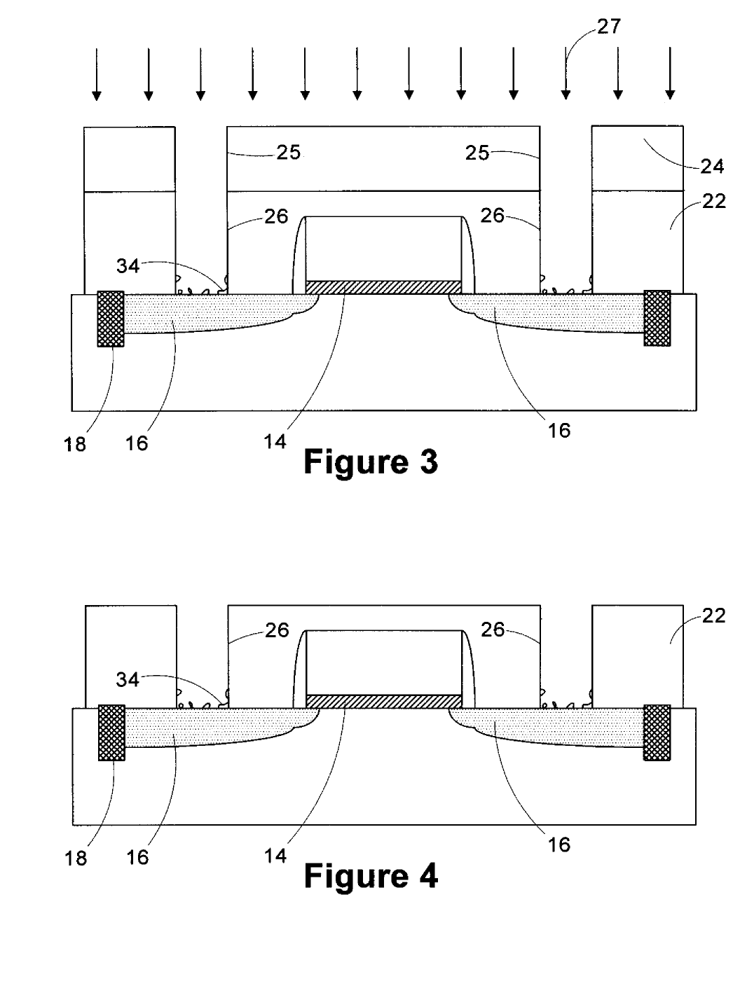

Next, as shown in FIG. 3, a plurality of openings 26 are formed in the insulating material 22 by performing an etching process, as schematically depicted by the arrows 27. In one illustrative embodiment, the etching process 27 is a dry plasma anisotropic etching process. The etching process 27 is performed for a sufficient duration so as to remove or clear the opening 26 of the insulating material 22 such that an effective electrical connection may be established to the device 10, i.e., to the source/drain regions 16. However, during the etching process, certain schematically depicted residual materials 34, e.g., polymers, insulating material, oxides, etc., may remain within the opening 26. As shown in FIG. 4, the patterned masking layer 24 is then removed. This may be accomplished by performing a variety of known techniques, e.g., an ashing process, a wet chemical strip, etc.

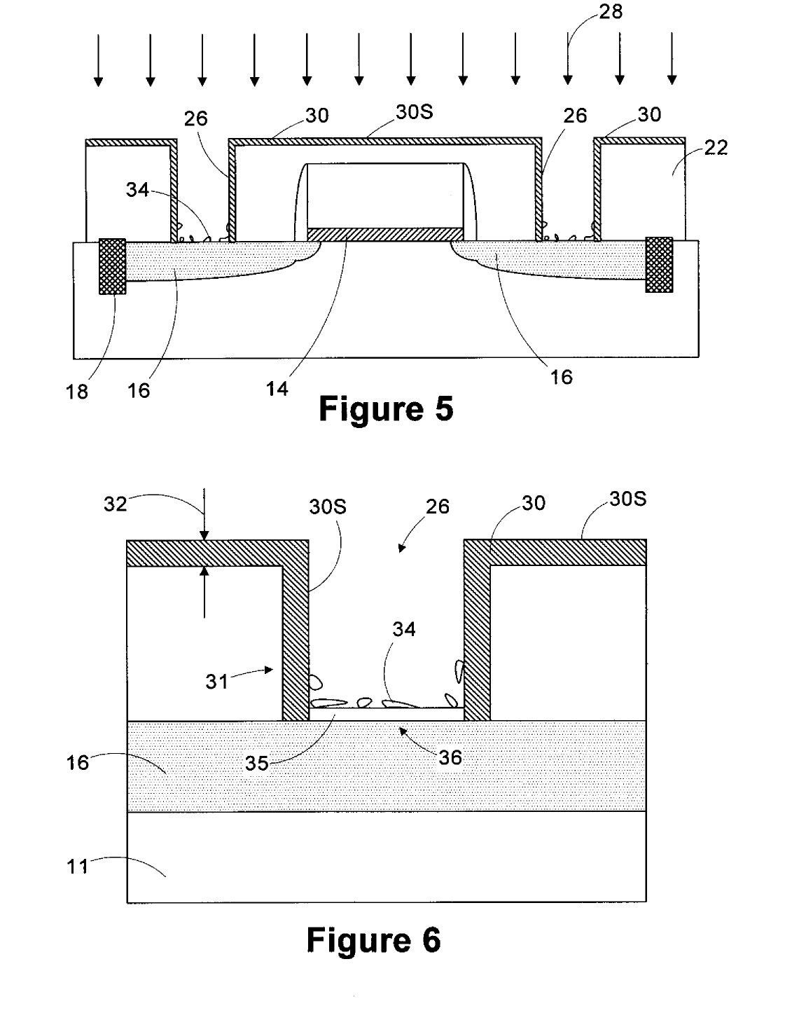

Next, as shown in FIG. 5, a plasma process, as indicated by the arrows 28, is performed to introduce nitrogen into a portion of the insulating material 22 to thereby form a nitrogen-containing region 30 in the exposed portions of the insulating material 22. In effect, the plasma process 28 converts a portion of the insulating material 22 into the nitrogen-containing region 30 or enhances the nitrogen concentration within the affected region 30 of the insulating material 22. That is, to the extent the material of the insulating material 22 comprises nitrogen, the plasma process 28 results in the region 30 having an enhanced or increased nitrogen concentration relative to the nitrogen concentration in the material of the insulating material 22. Thus, the use of the phrase nitrogen-enhanced to describe the region 30 should be understood to encompass situations where the insulating material 22 does not comprise any nitrogen as well as those where the insulating material 22 does comprise nitrogen. FIG. 6 is an enlarged view of the opening 26. To the extent that there is a layer of material 35 at the bottom 36 of the opening 26, the plasma process 28 also introduces nitrogen or forms a nitrogen-containing region in the layer of material 35.

The operational parameters for the plasma process 28 may vary depending upon the particular application. For example, in the case where the insulating material 22 is comprised of PSG, the plasma process 28 may be performed using ammonium (NH₃) as the source of nitrogen, at a pressure ranging from approximately 3-7 Torr, a power level of approximately 700-900 watts, and at a temperature ranging from approximately 550-650° C. In one illustrative example, the plasma process may be performed for a duration of approximately 60 seconds. Again, such illustrative parameters of the plasma process 28 are provided by way of example only as these parameters, and others, may vary depending upon the particular application. A variety of other process gases may be employed as the source of nitrogen for the plasma process 28, e.g., nitrogen, etc. The plasma process 28 may be performed in any of a variety of deposition or etching tools wherein plasmas may be generated under the appropriate process conditions, and the appropriate process gases may be introduced during the plasma process 28. The plasma process 28 may also be a decoupled plasma nitridization (DPN) process. In some cases, the plasma process may be performed such that the nitrogen penetrates throughout the thickness of the insulating material 22. The depth of the nitrogen penetration may be controlled by decreasing the temperature and/or time of the plasma process 28.

The thickness 32 of the nitrogen-containing region 30 may vary depending upon the particular application. In some cases, the thickness 32 may range from approximately 50-700 Å. The thickness 32 of the nitrogen-containing region 30 may not be uniform over the entirety of the insulating material 22. For example, the region 30 may have a greater thickness in areas where there are substantially flat surfaces of the insulating material 22 as compared to the thickness of the region 30 on the sidewalls 31 of the opening 26. The parameters of the plasma process 28 may be adjusted to ensure that the nitrogen-containing region 30 is formed on all desired surfaces to desired thickness levels. In one illustrative example, the nitrogen concentration of the region 30 may range from approximately 8×10²¹-2×10²² ions/cm. In one particular example, the outer surface 30S of the nitrogen-containing region 30 may have a nitrogen concentration of approximately 1-2×10²² ions/cm³. The concentration of nitrogen within the region 30 decreases with increasing depth from the outer surface 30S.

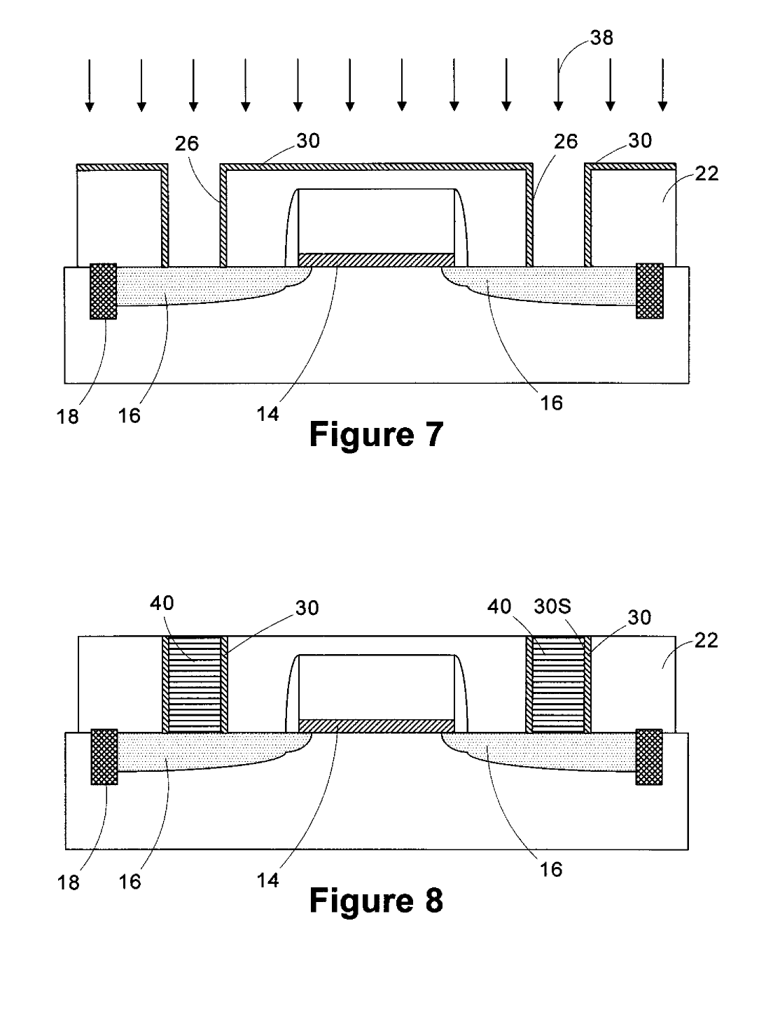

After the plasma process 28 is performed to introduce nitrogen into portions of the insulating material 22 and thereby convert portions of the insulating material 22 into the nitrogen-containing region 30, the device 10 may be subjected to additional processing to complete the formation of a conductive structure (not shown in FIG. 7) in the opening 26. For example, a “clean-up” etching process, as indicated by the arrows 38, may be performed to clean any residual materials 34 from the bottom 36 of the opening 26 to ensure that such undesirable materials 34 are removed. For example, the etching process 38 may be a wet etching process.

The presence of the nitrogen-containing region 30 during the clean-up etch process 38 helps to maintain dimensional integrity, i.e., the critical dimension, of the opening 26. That is, the formation of the nitrogen-containing region 30 effectively decreases the etchability of the insulating material 22 within the area of the opening 26. The formation of the nitrogen-containing region 30 acts, in effect, to reduce the etchability of the insulating material 22 such that there is less disparity between the etch rates of the undesirable material 34 and the opening 26. Thus, the etching process 38 may be performed for a sufficient duration and with a sufficiently aggressive etchant material such that the undesirable materials 34, 35 may be removed, while the nitrogen-containing region 30 tends to reduce the adverse impacts such an etching process would have on the dimensions of the opening 26 if the region 30 was not present.

After the etching process 38 is performed, conductive structures 40 may be formed in the openings 26 within the area defined by the region 30, as indicated in FIG. 8. In some cases, the device 10 may be exposed to ambient conditions prior to the formation of the conductive structures 40. In such cases, a wet etching process or chemical cleaning process may be performed to remove any native oxides (not shown), or other like materials, that may have formed in the opening 26 prior to the formation of the conductive structures 40. Of course, it is understood that there may be one or more barrier layers (not shown) or adhesion layers (not shown) positioned between the conductive material, e.g., metal, that comprises part of the conductive structure 40. Nevertheless, such a conductive structure 40 is still formed within the area defined by the region 30. Additionally, when it is stated that such a conductive structure 40 is formed proximate the region 30, that language is intended to cover situations where there may be one or more materials or layers actually positioned between the conductive structure 40 and the region 30 as well as situations where such additional layers are absent.

The conductive structures 40 may be comprised of any type of conductive material, e.g., a metal, copper, tungsten, etc., and it may be formed by a variety of known techniques. In the illustrative example depicted herein, one or more barrier layers (not shown) and/or adhesion layers (not shown) may be formed in the opening 26 as part of the process of forming the conductive structures 40. Thereafter, a conductive material may be blanket-deposited above the insulating material 22 and in the opening 26 using traditional deposition processes and techniques, e.g., CVD, plating processes, etc. Thereafter, a planarization process, such as a chemical mechanical polishing (CMP) process or an etching process, may be performed to remove the excess conductive material that is positioned outside of the openings 26, in accordance with known processing techniques.

What is claimed:

1. A method, comprising:
forming an opening in an insulating material;
performing a plasma process to introduce nitrogen into a portion of the insulating material to thereby form a nitrogen-containing region at least on an inner surface of the opening; and
after forming the nitrogen-containing region, performing an etching process through the opening.

2. The method of claim 1, wherein performing the plasma process comprises performing the plasma process using ammonium (NH₃) as a source of nitrogen to be introduced into the insulating material.

3. The method of claim 1, wherein the etching process is performed to remove undesirable material adjacent a bottom of the opening.

4. The method of claim 1, wherein the nitrogen-containing region has a thickness ranging from approximately 50-700 Å.

5. The method of claim 1, wherein the nitrogen-containing region has a nitrogen concentration of approximately 8×10²¹-2×10²² ions/cm³.

6. The method of claim 5, wherein the nitrogen-containing region has an outer surface with a nitrogen concentration of at least 1×10²² ions/cm³ nitrogen.

7. The method of claim 1, further comprising forming a conductive structure in the opening adjacent the nitrogen-containing region.

8. A method, comprising:
forming an opening in an insulating material;
converting a portion of the insulating material into a nitrogen-enhanced region of the insulating material; and
after converting the portion of the insulating material, performing an etching process through the opening.

9. The method of claim 8, wherein ammonium (NH₃) is used as a source of nitrogen in converting the portion of the insulating material into a nitrogen-enhanced region.

10. The method of claim 8, wherein the etching process is performed to remove undesirable material adjacent a bottom of the opening.

11. The method of claim 8, wherein the nitrogen-enhanced region has a thickness ranging from approximately 50-700 Å.

12. The method of claim 8, wherein the nitrogen-containing region has a nitrogen concentration of approximately 8×10²¹-2×10²² ions/cm³.

13. The method of claim 13, wherein the nitrogen-enhanced region has an outer surface with a nitrogen concentration of at least 1×10²² ions/cm³ nitrogen.

14. The method of claim 8, further comprising forming a conductive structure in the opening adjacent the nitrogen-enhanced region.

15. A device, comprising:
an insulating material comprising a nitrogen-enhanced region that is proximate an opening that extends through the insulating material; and
a conductive structure positioned within the opening.

16. The device of claim 15, wherein the layer of insulating material comprises an undoped silicon glass or a doped silicon glass.

17. The device of claim 15, wherein the nitrogen-enhanced region of the insulating material has a thickness ranging from approximately 50-700 Å.

18. The device of claim 15, wherein the conductive structure comprises a metal.

19. The device of claim 15, wherein the nitrogen-enhanced region of the insulating material lines the entirety of the opening.

20. The device of claim 15, wherein the conductive structure is conductively coupled to an underlying semiconductor device.

21. The device of claim 15, wherein the conductive structure is conductively coupled to a conductive line or via.

22. The device of claim 15, wherein the nitrogen-enhanced region of the insulating material has a nitrogen concentration that ranges from 8×10²¹-2×10²² ions/cm³.

23. The device of claim 15, wherein an outer surface of the nitrogen-enhanced region of the insulating material has a nitrogen concentration of at least 1×10²² ions/cm³ nitrogen.

24. A device, comprising:
an insulating material comprising a nitrogen-enhanced region having an outer surface that defines an opening that extends through the insulating material, the outer surface of the nitrogen-enhanced region having an increased concentration of nitrogen relative to a concentration of nitrogen in the insulating material; and
a conductive structure positioned within the opening.

25. The device of claim 24, wherein the nitrogen-enhanced region of the insulating material has a thickness ranging from approximately 50-700 Å.

26. The device of claim 24, wherein the conductive structure comprises a metal.

27. The device of claim 24, wherein the nitrogen-enhanced region of the insulating material has a nitrogen concentration that ranges from 8×10²¹-2×10²² ions/cm³.

28. The device of claim 24, wherein an outer surface of the nitrogen-enhanced region has a nitrogen concentration of at least 1×10²² ions/cm³ nitrogen.
